(19) United States
(12) Patent Application Publication
(10) Pub. No.: US 2026/0013106 A1
(43) Pub. Date: Jan. 8, 2026

(54) SEMICONDUCTOR MEMORY DEVICE

(71) Applicant: Samsung Electronics Co., Ltd., Suwon-si (KR)

(72) Inventors: Ja Yun Choi, Suwon-si (KR); Ji Eun Lee, Suwon-si (KR); Joon Suk Park, Suwon-si (KR); Han Jin Lim, Suwon-si (KR); In Tak Jeon, Suwon-si (KR)

(21) Appl. No.: 19/027,259

(22) Filed: Jan. 17, 2025

(30) Foreign Application Priority Data
Jul. 5, 2024 (KR) 10-2024-0088588

(51) Int. Cl. H10B 12/00; H10D 64/66; H10D 64/68

(52) U.S. Cl. CPC H10B 12/315; H10B 12/482; H10B 12/485; H10B 12/488; H10D 64/665; H10D 64/691

(57) ABSTRACT

A semiconductor memory device is provided. The semiconductor memory device may include a first electrode and a second electrode spaced apart from each other, a dielectric film structure between the first electrode and the second electrode, a first interfacial film between the first electrode and the dielectric film structure, and a second interfacial film between the second electrode and the dielectric film structure. The dielectric film structure may include a first dielectric film and a second dielectric film sequentially stacked on the first interfacial film. The first dielectric film may include an oxide of at least one of titanium (Ti) or strontium (Sr) having a first dielectric constant greater than 20. The second dielectric film may include a material having a second dielectric constant that is smaller than the first dielectric constant by at least 20.

### CROSS-REFERENCE TO RELATED APPLICATIONS

This application claims priority from Korean Patent Application No. 10-2024-0088588 filed on Jul. 5, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to a semiconductor memory device.

Recently, as semiconductor devices have become more highly integrated, a design rule for the semiconductor devices has continued to decrease. This trend is also observed in semiconductor memory devices, such as dynamic random-access memory (DRAM) devices. It is helpful for each DRAM memory cell to have at least a certain amount of capacitance so that the DRAM devices may operate efficiently.

Increasing the capacitance increases an amount of charges stored in the capacitor, thereby improving refresh characteristics of the semiconductor device. The improved refresh characteristics of the semiconductor device may improve a yield of the semiconductor device.

### SUMMARY OF THE INVENTION

Aspects of the present disclosure provide a semiconductor memory device having increased capacitance and reduced stress.

According to some aspects of the present disclosure, there is provided a semiconductor memory device comprising a first electrode and a second electrode spaced apart from each other, a dielectric film structure between the first electrode and the second electrode, a first interfacial film between the first electrode and the dielectric film structure, and a second interfacial film between the second electrode and the dielectric film structure, wherein the dielectric film structure includes a first dielectric film and a second dielectric film sequentially stacked on the first interfacial film, wherein the first dielectric film includes an oxide of at least one of titanium (Ti) or strontium (Sr) having a first dielectric constant greater than 20, and wherein the second dielectric film includes a material having a second dielectric constant that is smaller than the first dielectric constant by at least 20.

According to some aspects of the present disclosure, there is provided a semiconductor memory device comprising a first electrode and a second electrode spaced apart from each other, and a first interfacial film, a plurality of dielectric film structures, and a second interfacial film that are between the first electrode and the second electrode and are sequentially stacked, wherein the first interfacial film is in direct contact with the first electrode, and the second interfacial film is in direct contact with the second electrode, wherein the plurality of dielectric film structures are sequentially stacked on the first interfacial film, wherein a first one of the plurality of dielectric film structures includes first and second dielectric films, and a second one of the plurality of dielectric film structures includes third and fourth dielectric films, wherein the first to fourth dielectric films respectively include first to fourth materials having respective first to fourth dielectric constants, wherein each of the first dielectric constant and the third dielectric constant is greater than 20, and wherein each of the second dielectric constant and the fourth dielectric constant is smaller than each of the first dielectric constant and the third dielectric constant by at least 20.

According to some aspects of the present disclosure, there is provided a semiconductor memory device comprising a substrate including an active area that is defined by an element isolation film and that extends in a first direction, wherein the active area includes a first portion and a second portion on opposing sides of the first portion, a word line extending in a second direction different from the first direction, wherein the word line extends across an area between the first portion of the active area and the second portion of the active area, a bit line contact electrically connected to the first portion of the active area, a bit line on the bit line contact and electrically connected to the bit line contact, wherein the bit line extends in a third direction different from the first direction and the second direction, and a capacitor structure including a lower electrode electrically connected to the second portion of the active area, the capacitor structure further including a lower interfacial film, a dielectric film structure, an upper interfacial film, and an upper electrode sequentially stacked on the lower electrode, wherein the dielectric film structure includes a first dielectric film structure and a second dielectric film structure, wherein each of the first dielectric film structure and the second dielectric film structure includes a first dielectric film and a second dielectric film, wherein the first dielectric film and the second dielectric film of the first dielectric film structure and the first dielectric film and the second dielectric film of the second dielectric film structure are sequentially stacked on top of each other, wherein the first dielectric film includes an oxide of at least one of titanium (Ti) or strontium (Sr) having a first dielectric constant greater than 20, and wherein the second dielectric film includes a material having a second dielectric constant that is smaller than the first dielectric constant by at least 20.

According to some aspects of the present disclosure, a capacitor may include a dielectric film having a high dielectric constant and/or a contact area between the dielectric film and a lower electrode of the capacitor may be increased to increase the capacitance of a semiconductor memory device.

However, aspects of the present disclosure are not limited to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail example embodiments thereof with reference to the accompanying drawings, in which:

FIG. 1 is a diagram for illustrating a semiconductor memory device according to some embodiments.

FIG. 2 is an enlarged view of a portion P of FIG. 1.

FIG. 3 is an enlarged view of the portion P of FIG. 1 according to some further embodiments.

FIG. 4 is an enlarged view of the portion P of FIG. 1 according to some further embodiments.

FIG. 5 is a layout diagram of a semiconductor memory device according to some embodiments.

FIG. 6 is a layout diagram showing only a word line and a cell active area of FIG. 5.

FIG. 7 is a cross-sectional view taken along line A-A of FIG. 5.

FIG. 8 is a layout diagram of a semiconductor memory device according to some further embodiments.

FIG. 9 is a cross-sectional view taken along line A-A of FIG. 8.

FIG. 10 is a layout diagram for illustrating a semiconductor memory device according to some embodiments.

FIG. 11 is a perspective view for illustrating a semiconductor memory device according to some embodiments.

FIG. 12 is a cross-sectional view taken along lines B-B and C-C of FIG. 10.

FIG. 13 is a layout diagram for illustrating a semiconductor memory device according to some embodiments.

FIG. 14 is a perspective view for illustrating a semiconductor memory device according to some embodiments.

FIGS. 15 to 21 are diagrams of intermediate structures corresponding to intermediate steps of a method for manufacturing a semiconductor memory device according to some embodiments.

### DETAILED DESCRIPTION

Although terms such as “first”, “second”, “third”, etc. may be used herein to describe various elements or components, it will be understood that these element or components are not limited by these terms. Rather, these terms are merely used to distinguish one element or component from another element or component. Therefore, it will be understood that a first element or component as used herein may also be termed a second element or component, without departing from the scope of the present disclosure. As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

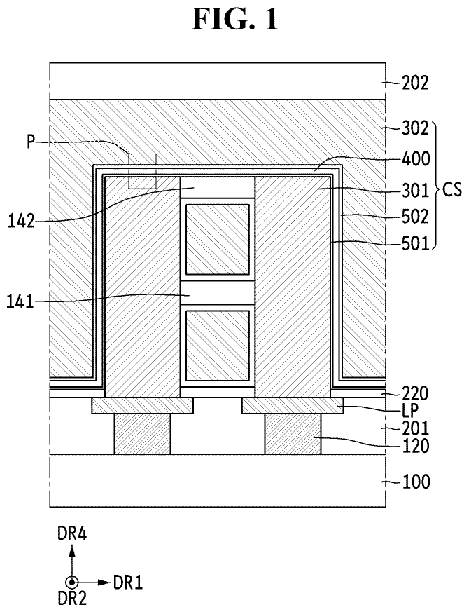

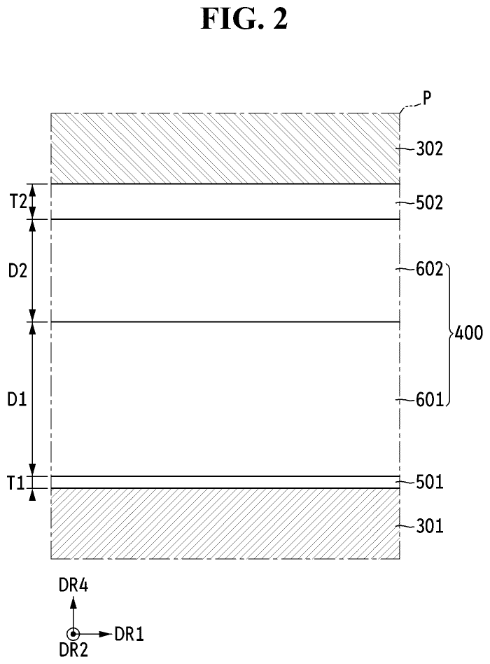

FIG. 1 is a diagram for illustrating a semiconductor memory device according to some embodiments. FIG. 2 is an enlarged view of a portion P of FIG. 1.

Referring to FIG. 1 and FIG. 2, a semiconductor memory device according to some embodiments may include a substrate 100, a first interlayer insulating film 201, a storage contact 120, a landing pad LP, an etch stop layer 220, a capacitor structure CS (which may also be referred to as a data storage pattern), a lower supporter pattern 141, an upper supporter pattern 142, and a second interlayer insulating film 202.

The substrate 100 may be made of bulk silicon or SOI (silicon-on-insulator). In some embodiments, the substrate 100 may be embodied as a silicon substrate, or may be made of a material other than silicon, such as silicon germanium, SGOI (silicon germanium on insulator), indium antimonide, a lead telluride compound, indium arsenide, indium phosphide, gallium arsenide or gallium antimonide. However, the present disclosure is not limited thereto. In the following description, an example in which the substrate 100 is embodied as a silicon substrate is described, but the present disclosure is not limited thereto.

The first interlayer insulating film 201 may be disposed on the substrate 100. The first interlayer insulating film 201 may include, for example, at least one of silicon oxide, silicon nitride, silicon oxynitride (SiON), silicon oxycarbonitride (SiOCN), or combinations thereof.

The storage contact 120 may be disposed on the substrate 100. Specifically, the storage contact 120 may be surrounded with the first interlayer insulating film 201. The storage contact 120 may include, for example, at least one of an impurity-doped semiconductor material, a conductive silicide compound, a conductive metal nitride, or a metal.

The landing pad LP may be disposed on the substrate 100. The landing pad LP may include, for example, at least one of an impurity-doped semiconductor material, a conductive silicide compound, a conductive metal nitride, or a metal. In a semiconductor memory device according to some embodiments, the landing pad LP may include tungsten (W).

The etch stop layer 220 may be disposed on the first interlayer insulating film 201. The etch stop layer 220 may expose at least a portion of the landing pad LP. For example, the etch stop layer 220 may be disposed on the landing pad LP. The etch stop layer 220 may include a lower electrode hole that exposes at least a portion of the landing pad LP.

The etch stop layer 220 may include, for example, at least one of silicon nitride (SiN), silicon carbonitride (SiCN), silicon boron nitride (SiBN), silicon carbonoxide (SiCO), silicon oxynitride (SiON), silicon oxide (SiO), or silicon oxycarbonitride (SiOCN). For example, silicon carbonoxide (SiCO) is composed of silicon (Si), carbon (C) and oxygen (O), wherein a ratio between contents of silicon (Si), carbon (C) and oxygen (O) is not limited to a specific value.

The capacitor structure CS may be disposed on the landing pad LP. The capacitor structure CS may include a lower electrode 301, a lower interfacial film 501, a dielectric film structure 400, an upper interfacial film 502, and an upper electrode 302.

The lower electrode 301 (which may also be referred to as a first electrode) may be disposed on the landing pad LP. The lower electrode 301 may be connected to the landing pad LP.

The lower electrode 301 may extend in a fourth direction DR4. A length by which the lower electrode 301 extends in the fourth direction DR4 may be greater than a length by which the lower electrode 301 extends in a first direction DR1. In some embodiments, the length by which the lower electrode 301 extends in the fourth direction DR4 is greater than a width in the first direction DR1 of the lower electrode 301. The lower electrode 301 may have, for example, a pillar-shaped shape.

In this regard, the fourth direction DR4 may be a direction parallel to a thickness direction of the substrate 100. For example, the fourth direction DR4 may be perpendicular to an upper surface of the substrate 100 and/or an upper surface of the first interlayer insulating film 201. The first direction DR1 may intersect the fourth direction DR4 and may be a direction parallel to the upper surface of the substrate 100 and/or the upper surface of the first interlayer insulating film 201. A second direction DR2 may intersect the first direction DR1 and the fourth direction DR4 and may be a direction parallel to the upper surface of the substrate 100 and/or the upper surface of the first interlayer insulating film 201.

A portion of the lower electrode 301 may be disposed within the etch stop layer 220. The lower electrode 301 may extend through the etch stop layer 220 so as to be connected to the landing pad LP. For example, a portion of a sidewall of the lower electrode 301 may be in contact with the etch stop layer 220.

The lower electrode 301 may include, for example, a doped semiconductor material, a conductive metal nitride such as titanium nitride, tantalum nitride, niobium nitride, tungsten nitride, etc., a metal such as ruthenium, iridium, titanium, tantalum, etc., or a conductive metal oxide such as iridium oxide, niobium oxide, etc. However, the present disclosure is not limited thereto. In the semiconductor device according to some embodiments, the lower electrode 301 may include titanium nitride (TiN). Furthermore, in some embodiments, the lower electrode 301 may include niobium nitride (NbN). In some embodiments, the lower electrode 301 may not include ruthenium (Ru), platinum (Pt), gold (Au), and palladium (Pd). That is, expensive materials such as ruthenium (Ru), platinum (Pt), gold (Au), and palladium (Pd) may not be used when manufacturing the lower electrode 301. Therefore, a process cost required for a manufacturing process of the semiconductor memory device may be reduced.

The lower supporter pattern 141 may be disposed on the etch stop layer 220. The lower supporter pattern 141 may be spaced apart from the etch stop layer 220 in the fourth direction DR4. The lower supporter pattern 141 may be in contact with the lower electrode 301. The lower supporter pattern 141 may be in contact with a portion of the side wall of the lower electrode 301.

The lower supporter pattern 141 may connect the lower electrodes 301 adjacent to each other in the first direction DR1 to each other. In FIG. 1, it is illustrated that two lower electrodes 301 are connected to each other via the lower supporter pattern 141. However, this is only for the convenience of illustration and the present disclosure is not limited thereto.

The upper supporter pattern 142 may be disposed on the lower supporter pattern 141. The upper supporter pattern 142 may be spaced apart from the lower supporter pattern 141 in the fourth direction DR4. The upper supporter pattern 142 may be in contact with the lower electrode 301. The upper supporter pattern 142 may be in contact with a portion of the side wall of the lower electrode 301.

The upper supporter pattern 142 may connect the lower electrodes 301 adjacent to each other in the first direction DR1. In FIG. 1, two lower electrodes 301 are shown as being connected to each other via the upper supporter pattern 142. However, this is only for the convenience of illustration and the present disclosure is not limited thereto.

In one example, as shown, an upper surface of the upper supporter pattern 142 may be coplanar with an upper surface of the lower electrode 301. In another example, an upper surface of the lower electrode 301 may protrude in the fourth direction DR4 away from the substrate 100 and beyond the upper surface of the upper supporter pattern 142. In descriptions as set forth below, an example in which the upper surface of the upper supporter pattern 142 is coplanar with the upper surface of the lower electrode 301 is described, but the present disclosure is not limited thereto.

Each of the lower supporter pattern 141 and the upper supporter pattern 142 may include at least one of, for example, silicon nitride (SiN), silicon carbonitride (SiCN), silicon boron nitride (SiBN), silicon carbonate (SiCO), silicon oxynitride (SiON), silicon oxide (SiO), or silicon oxycarbonitride (SiOCN). In a semiconductor memory device according to some embodiments, each of the lower supporter pattern 141 and the upper supporter pattern 142 may include silicon carbonitride (SiCN) or silicon nitride (SiN).

The lower interfacial film 501 (which may also be referred to as a first interfacial film) may be present in a thin film form on (e.g., covering) the lower electrode 301, the etch stop layer 220, and the upper supporter pattern 142. The lower interfacial film 501 may be disposed between the lower electrode 301 and the dielectric film structure 400 to be described later, thereby increasing crystallinity of the dielectric film structure 400. In other words, the crystallinity of the dielectric film structure 400 may be increased by the lower interfacial film 501, thereby increasing capacitance of the capacitor. A thickness T1 of the lower interfacial film 501 may be in a range of about 1 angstrom (Å) to 10 Å. As used herein, the phrase “in a range of X to Y” (or similar language) includes both X and Y, as well as all values between X and Y.

The lower interfacial film 501 may be embodied as a single film (e.g., a single-layered film). The lower interfacial film 501 may include, but is not limited to, one of tantalum oxide, antimony oxide, molybdenum oxide, cobalt oxide, niobium oxide, copper oxide, nickel oxide, vanadium oxide, tungsten oxide, tantalum nitride, antimony nitride, molybdenum nitride, cobalt nitride, niobium nitride, copper nitride, nickel nitride, vanadium nitride, tungsten nitride, or combinations thereof. In other words, the lower interfacial film 501 may include an oxide or a nitride of at least one of tantalum (Ta), antimony (Sb), molybdenum (Mo), cobalt (Co), niobium (Nb), copper (Cu), nickel (Ni), vanadium (V), or tungsten (W).

The dielectric film structure 400 may be preset in a thin film form on (e.g., covering) the lower electrode 301, the etch stop layer 220, the upper support pattern 142, and the lower interfacial film 501. In other words, the dielectric film structure 400 may extend along a profile of the lower interfacial film 501. The dielectric film structure 400 may be disposed between the lower interfacial film 501 and the upper interfacial film 502. The dielectric film structure 400 may be disposed between the upper electrode 302 and the lower electrode 301. In FIG. 1, the dielectric film structure 400 is illustrated as being embodied as a single film. However, this is only for the convenience of illustration and the present disclosure is not limited thereto.

The dielectric film structure 400 may include a first dielectric film 601 and a second dielectric film 602. The first dielectric film 601 may be in direct contact with the lower interfacial film 501. The second dielectric film 602 may be stacked on the first dielectric film 601. The second dielectric film 602 may be in direct contact with the upper interfacial film 502 to be described later.

The first dielectric film 601 may include a high-k dielectric material having a first dielectric constant K1. The first dielectric constant K1 may be greater than 20. The second dielectric film 602 may include a low-k dielectric material having a second dielectric constant K2. The second dielectric constant K2 may be smaller than the first dielectric constant K1 by 20 or larger (i.e., by at least 20). A polarization relaxation phenomenon occurs due to a difference between the first dielectric constant K1 and the second dielectric constant K2. This may increase the capacitance of the capacitor by causing polarity at an interface between the first dielectric film 601 and the second dielectric film 602. When the difference between the second dielectric constant K2 and the first dielectric constant K1 is smaller than 20, the difference between the dielectric constants may not be sufficient, so that the capacitance of the capacitor may not be improved.

The first dielectric film 601 may include one of titanium oxide, strontium oxide, or a combination thereof. In other words, the first dielectric film 601 may include an oxide of at least one of titanium (Ti) or strontium (Sr). The second dielectric film 602 may include one of aluminum oxide, yttrium oxide, lanthanum oxide, boron oxide, indium oxide, or a combination thereof. In other words, the second dielectric film 602 may include an oxide of at least one of aluminum (Al), yttrium (Y), lanthanum (La), boron (B), or indium (In).

For example, when the first dielectric film 601 includes titanium oxide, the second dielectric film 602 may include lanthanum oxide. In this case, since the dielectric constant of titanium oxide is in a range of about 80 to 100 and the dielectric constant of lanthanum oxide is about 27, the difference between the first dielectric constant K1 and the second dielectric constant K2 is larger than 20.

A thickness D1 of the first dielectric film 601 may be larger than a thickness D2 of the second dielectric film 602. The thickness D1 of the first dielectric film 601 may be, for example, in a range of about 50 Å to 100 Å. The thickness D2 of the second dielectric film 602 may be, for example, in a range of about 20 Å to 40 Å. In some embodiments, the thickness D2 of the second dielectric film 602 may be in a range of 30% to 60% of the thickness D1 of the first dielectric film 601. The first dielectric film 601 having the higher dielectric constant is thicker than the second dielectric film 602, so that the reliability and performance of the semiconductor memory device may be improved.

The upper interfacial film 502 (which may also be referred to as a second interfacial film) may be present in a thin film form on (e.g., covering) the dielectric film structure 400. The upper interfacial film 502 may be disposed between the dielectric film structure 400 and the upper electrode 302 to be described later. The upper interfacial film 502 may extend along a profile of the dielectric film structure 400. A thickness T2 of the upper interfacial film 502 may be in a range of about 5 Å to 20 Å. In some embodiments, the thickness T2 of the upper interfacial film 502 may be greater than the thickness T1 of the lower interfacial film 501.

The upper interfacial film 502 may include, but is not limited to, one of tantalum oxide, antimony oxide, molybdenum oxide, cobalt oxide, niobium oxide, copper oxide, nickel oxide, vanadium oxide, tungsten oxide, tantalum nitride, antimony nitride, molybdenum nitride, cobalt nitride, niobium nitride, copper nitride, nickel nitride, vanadium nitride, tungsten nitride, or combinations thereof.

The upper electrode 302 (which may also be referred to as a second electrode) may be disposed on the capacitor upper interfacial film 502. The upper electrode 302 may extend along a profile of the upper interfacial film 502. The upper electrode 302 may include at least one of, but is not limited to, a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide). In some embodiments, the upper electrode 302 may include titanium nitride (TiN). Furthermore, in some embodiments, the upper electrode 302 may include niobium nitride (NbN). In some embodiments, the upper electrode 302 may not include ruthenium (Ru), platinum (Pt), gold (Au), and palladium (Pd).

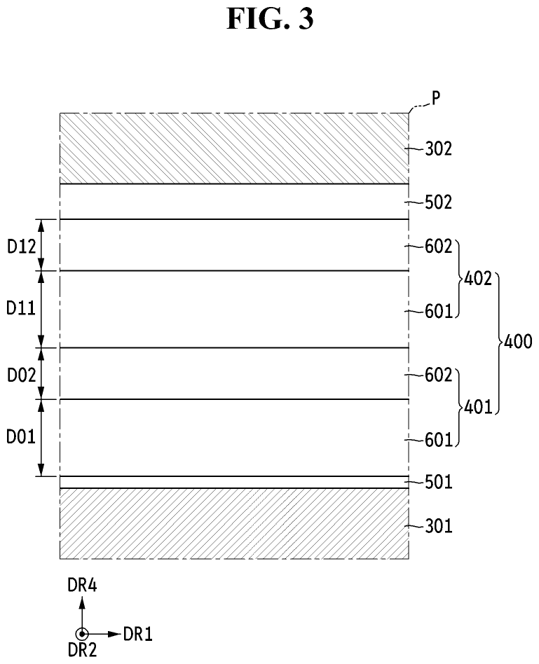

FIG. 3 is an enlarged view of the portion P of FIG. 1 according to some further embodiments. For convenience of description, the following description mainly focuses on differences thereof from the description above with reference to FIG. 1 and FIG. 2.

Referring to FIG. 3, the dielectric film structure 400 may include a first dielectric film structure 401 and a second dielectric film structure 402. Each of the first dielectric film structure 401 and the second dielectric film structure 402 may include a first dielectric film 601 and a second dielectric film 602. The first dielectric film 601 of the first dielectric film structure 401 may be in direct contact with the lower interfacial film 501. The second dielectric film 602 of the second dielectric film structure 402 may be in direct contact with the upper interfacial film 502.

The first dielectric film 601 of the second dielectric film structure 402 may be stacked on the second dielectric film 602 of the first dielectric film structure 401. In other words, the first dielectric films 601 including a high-k dielectric material and the second dielectric films 602 including a low-k dielectric material may be alternately stacked on top of each other. For example, the first dielectric film 601 and the second dielectric film 602 of the first dielectric film structure 401 and the first dielectric film 601 and the second dielectric film 602 of the second dielectric film structure 402 may be sequentially stacked on top of each other.

The first dielectric film 601 of the first dielectric film structure 401 may have a thickness DO1, the second dielectric film 602 of the first dielectric film structure 401 may have a thickness DO2, the first dielectric film 601 of the second dielectric film structure 402 may have a thickness D11, and the second dielectric film 602 of the second dielectric film structure 402 may have a thickness D12. For example, the thicknesses DO1 and D11 may be greater than the thicknesses D02 and D12. In some embodiments, a combined thickness of the second dielectric film 602 of the first dielectric film structure 401 and the second dielectric film 602 of the second dielectric film structure 402 (i.e., D02+D12) may be in a range of 30% to 60% of a combined thickness of the first dielectric film 601 of the first dielectric film structure 401 and the first dielectric film 601 of the second dielectric film structure 402 (i.e., D01+D11).

The first dielectric film 601 of the first dielectric film structure 401 and the first dielectric film 601 of the second dielectric film structure 402 may include the same material. However, embodiments of the present disclosure are not limited thereto. In another example, the first dielectric film 601 of the first dielectric film structure 401 and the first dielectric film 601 of the second dielectric film structure 402 may include different materials. The second dielectric film 602 of the first dielectric film structure 401 and the second dielectric film 602 of the second dielectric film structure 402 may include the same material. However, embodiments of the present disclosure are not limited thereto. In another example, the second dielectric film 602 of the first dielectric film structure 401 and the second dielectric film 602 of the second dielectric film structure 402 may include different materials.

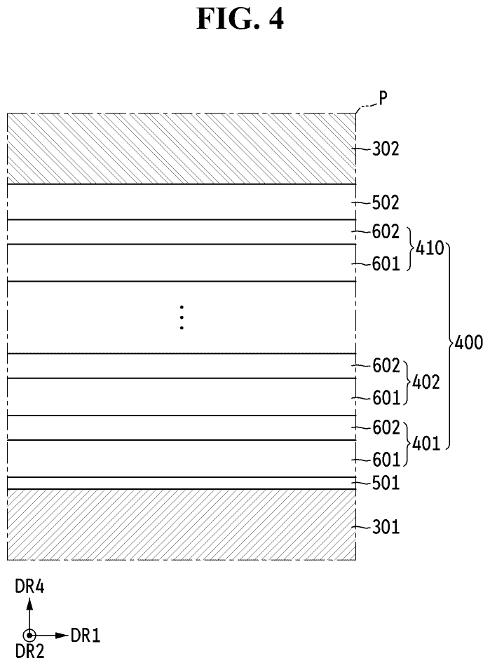

FIG. 4 is an enlarged view of the portion P of FIG. 1 according to some further embodiments. For convenience of description, the following description mainly focuses on differences thereof from the description above with reference to FIG. 1 and FIG. 2.

Referring to FIG. 4, the dielectric film structure 400 may include first to tenth dielectric film structures 401 to 410. Each of the first to tenth dielectric film structures 401 to 410 may include the first dielectric film 601 and the second dielectric film 602. For example, the first dielectric film 601 and the second dielectric film 602 may be repeatedly stacked in sequence across the first to tenth dielectric film structures 401 to 410, with each of the first to tenth dielectric film structures 401 to 410 including the first dielectric film 601 and the second dielectric film 602.

The first dielectric film 601 of the first dielectric film structure 401 may be in direct contact with the lower interfacial film 501. The second dielectric film 602 of the 10th dielectric film structure 410 may be in direct contact with the upper interfacial film 502. The second to tenth dielectric film structures 402 to 410 may be sequentially stacked on the first dielectric film structure 401. In other words, the first dielectric film 601 including a high-k dielectric material and the second dielectric film 602 including a low-k dielectric material may be alternately stacked on top of each other.

The respective first dielectric films 601 of the first to tenth dielectric film structures 401 to 410 may include the same material. However, embodiments of the present disclosure are not limited thereto. In another example, the respective first dielectric film 601 of the first to tenth dielectric film structures 401 to 410 may include different materials. The respective second dielectric films 602 of the first to tenth dielectric film structures 401 to 410 may include the same material. However, embodiments of the present disclosure are not limited thereto. In another example, the respective second dielectric films 602 of the first to tenth dielectric film structures 401 to 410 may include different materials.

In FIG. 4, an example in which the first to tenth dielectric film structures 401 to 410 are sequentially stacked is shown. However, embodiments of the present disclosure are not limited thereto. In another example, 11 or more dielectric film structures 400 may be sequentially stacked.

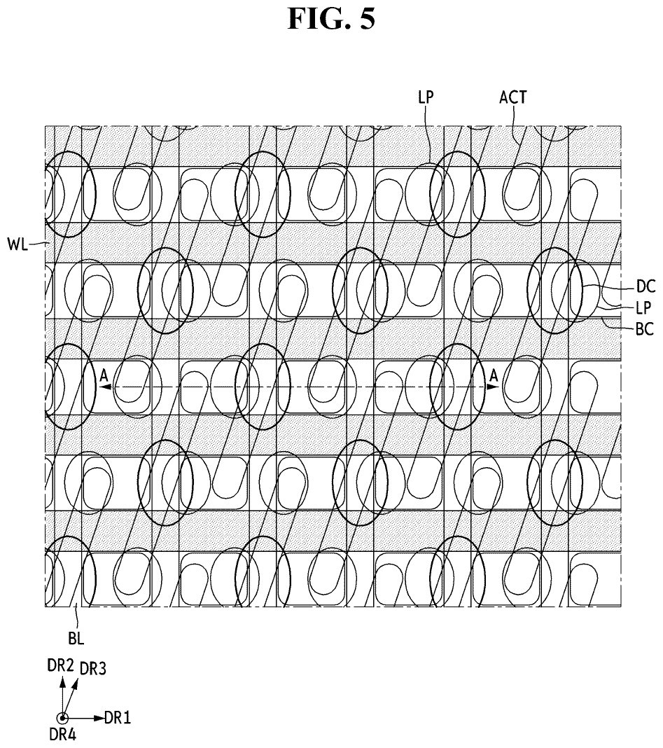

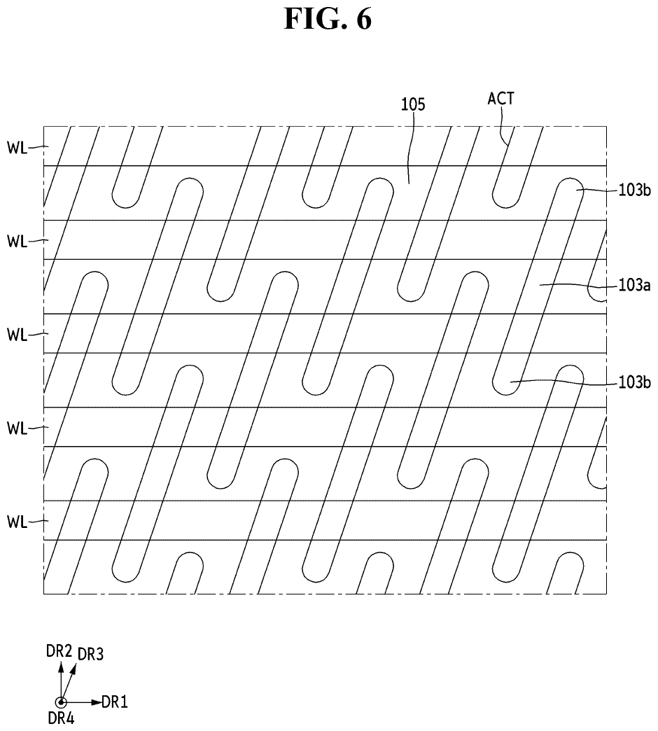

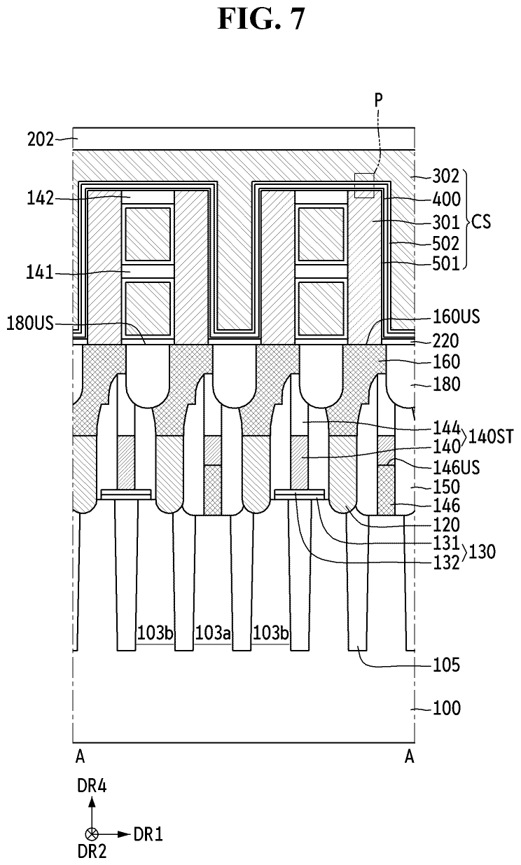

FIG. 5 is a layout diagram of a semiconductor memory device according to some embodiments. FIG. 6 is a layout diagram showing only a word line and a cell active area of FIG. 5. FIG. 7 is a cross-sectional view taken along line A-A of FIG. 5.

For reference, FIG. 5 illustrates an example layout of a DRAM (Dynamic Random-Access Memory) excluding the capacitor structure CS. However, embodiments of the present disclosure are not limited thereto. Like reference numbers in FIGS. 5 to 7 refer to like elements in FIGS. 1 to 4.

Furthermore, the first direction DR1 of FIG. 5 may correspond to the first direction DR1 of FIG. 1, the second direction DR2 of FIG. 5 may correspond to the second direction DR2 of FIG. 1, and the fourth direction DR4 of FIG. 5 may correspond to the fourth direction DR4 of FIG. 1. However, embodiments of the present disclosure are not limited thereto. Unlike the above definition, the first direction DR1 of FIG. 5 may correspond to the second direction DR2 of FIG. 1, and the second direction DR2 of FIG. 5 may correspond to the first direction DR1 of FIG. 1.

Referring to FIGS. 5 to 7, a semiconductor memory device according to some further embodiments may include a plurality of cell active areas ACT.

The cell active area ACT may be defined by a cell element isolation film 105 formed within the substrate 100. As the design rule of the semiconductor memory device is reduced, the cell active area ACT may extend in a bar shape of a diagonal line or an oblique line as shown. For example, the cell active area ACT may extend in a third direction DR3.

A plurality of gate electrodes may be disposed so as to extend across the cell active area ACT in the first direction DR1. The plurality of gate electrodes may extend in a parallel manner to each other. The plurality of gate electrodes may be, for example, a plurality of word lines WL. The word lines WL may be arranged so as to be spaced from each other by an equal spacing (e.g., in the second direction DR2). A width of the word line WL or the spacing between the word lines WL may be determined according to the design rule.

Two word lines WL extending in the first direction DR1 may divide each cell active area ACT into three portions. The cell active area ACT may include a storage connection area 103b and a bit line connection area 103a. The bit line connection area 103a may be positioned at a middle portion of the cell active area ACT, and the storage connection area 103b may be positioned at each of both opposing ends of the cell active area ACT. In other words, the cell active area ACT may include a first portion (i.e., the bit line connection area 103a) and a second portion (i.e., the storage connection area 103b) on opposing sides of the first portion (e.g., in the third direction DR3). For example, the word line WL may extend across an area between the first portion and the second portion of the cell active area ACT (e.g., see FIG. 6.)

For example, the bit line connection area 103a may be an area connected to a bit line BL, and the storage connection area 103b may be an area connected to a data storage pattern CS (i.e., a capacitor structure). For example, the bit line connection area 103a of the cell active area ACT may be connected to a cell conductive line 140, and the storage connection area 103b of the cell active area ACT may be connected to a lower electrode 301 of the capacitor structure CS. In other words, the bit line connection area 103a may correspond to a common drain area, and the storage connection area 103b may correspond to a source area. Each word line WL and the bit line connection area 103a and the storage connection area 103b adjacent thereto may constitute a transistor.

A plurality of bit lines BL extending in the second direction DR2 orthogonal to the word line WL may be disposed on the word line WL. The plurality of bit lines BL may extend in a parallel manner to each other. The bit lines BL may be arranged so as to be spaced from each other by an equal spacing (e.g., in the first direction DR1). A width of the bit line BL or the spacing between the bit lines BL may be determined according to the design rule.

A fourth direction DR4 may be orthogonal to a plane defined by the first direction DR1, the second direction DR2, and the third direction DR3.

A semiconductor memory device according to some embodiments may include various contact arrangements formed on the cell active area ACT. The various contact arrangements may include, for example, direct contacts DC, buried contacts BC, and landing pads LP.

In this regard, the direct contact DC may mean a contact that electrically connects the cell active area ACT to the bit line BL. The buried contact BC may mean a contact that connects the cell active area ACT to the lower electrode 301 of the data storage pattern CS.

Due to the arrangement structure, a contact area between the buried contact BC and the cell active area ACT may be small. Accordingly, a conductive landing pad LP may be introduced to expand the contact area thereof with the cell active area ACT and the contact area thereof with the lower electrode 301 of the data storage pattern CS.

In a semiconductor memory device according to some embodiments, the landing pad LP may be disposed between the buried contact BC and the lower electrode 301 of the data storage pattern CS. The contact area may be increased through the introduction of the landing pad LP, such that a contact resistance between the cell active area ACT and the lower electrode 301 of the data storage pattern CS may be reduced.

In a semiconductor memory device according to some embodiments, the direct contact DC may be disposed in a position overlapping the middle portion of the cell active area ACT (e.g., in the fourth direction DR4). As used herein, “an element A overlaps an element B in a direction X” (or similar language) means that there is at least one straight line that extends in the direction X and intersects both the elements A and B. The buried contact BC may be disposed in a position overlapping each of both opposing ends of the cell active area ACT (e.g., in the fourth direction DR4). The direct contact DC may be connected to the bit line connection area 103a. The buried contact BC may be connected to the storage connection area 103b.

As the buried contact BC is disposed in a position overlapping each of both opposing ends of the cell active area ACT, the landing pad LP may be disposed adjacent to each of both opposing ends of the cell active area ACT and may partially overlap with the buried contact BC (e.g., in the fourth direction DR4). In other words, the buried contact BC may be formed to overlap the cell active area ACT and the element isolation film 105 between adjacent word lines WL and between adjacent bit lines BL.

The word line WL may be formed as a structure buried in the substrate 100. The word line WL may be disposed to extend across the active area ACT between the direct contacts DC or the buried contacts BC.

As illustrated, two word lines WL may be disposed to extend across one active area ACT. Since the active area ACT extends in a diagonal shape, the extension direction of the word line WL may have an angle smaller than 90 degrees with respect to the extension direction of the active area ACT.

The direct contacts DC and the buried contacts BC may be arranged in a symmetrical manner. Thus, the direct contacts DC may be arranged along the first direction DR1 and the second direction DR2. The buried contacts BC may be arranged along the first direction DR1 and the second direction DR2.

In one example, unlike the direct contact DC and the buried contact BC, the landing pads LP may be arranged in a zigzag manner in the second direction DR2 in which the bit line BL extends. Further, the landing pads LP may overlap with the same portion of a side face of each bit line BL in the first direction DR1 in which the word line WL extends.

For example, each of the landing pads LP in a first line may overlap a left side face of a corresponding bit line BL, while each of the landing pads LP in a second line may overlap with a right side face of the corresponding bit line BL.

A semiconductor memory device according to some embodiments may include a plurality of bit line structures 140ST, a plurality of storage contacts 120, a plurality of bit line contacts 146, and a capacitor structure CS.

The cell element isolation film 105 may be disposed within the substrate 100. The cell element isolation film 105 may have a shallow trench isolation (STI) structure having excellent element isolation characteristics. The cell element isolation film 105 may define the cell active area ACT within a memory cell area.

The cell active area ACT defined by the cell element isolation film 105 may have a long island shape including a short axis and a long axis as illustrated in FIG. 5 and FIG. 6. The cell active area ACT may have an oblique shape so as to have an angle smaller than 90 degrees with respect to the word line WL formed within the cell element isolation film 105. Furthermore, the cell active area ACT may have an oblique shape so as to have an angle smaller than 90 degrees with respect to the bit line BL formed on the cell element isolation film 105.

The cell element isolation film 105 may include, but is not limited to, for example, at least one of a silicon oxide film, a silicon nitride film, or a silicon nitride film. The cell element isolation film 105 is illustrated as being formed as a single insulating film. However, this is only for the convenience of illustration and the present disclosure is not limited thereto. Depending on a distance between adjacent cell active areas ACT, the cell element isolation film 105 may be formed as one insulating film or may be formed as a plurality of insulating films.

The bit line structure 140ST may include a cell conductive line 140, a cell line capping film 144, and a bit line spacer 150.

The cell conductive line 140 may be disposed on the substrate 100 and the cell element isolation film 105 in which the word line WL has been formed. The cell conductive line 140 may intersect the cell element isolation film 105 and the cell active area ACT defined by the cell element isolation film 105. The cell conductive line 140 may be formed to intersect the word line WL. In this regard, the cell conductive line 140 may correspond to the bit line BL. For example, the cell conductive line 140 may be the bit line BL of FIG. 5.

The cell conductive line 140 may include, for example, at least one of a semiconductor material doped with an impurity, a conductive silicide compound, a conductive metal nitride, a two-dimensional 2D material, or a metal.

The cell conductive line 140 is illustrated as being embodied as a single film. However, this is only for convenience of illustration and the present disclosure is not limited thereto. That is, unlike what is illustrated, the cell conductive line 140 may include a plurality of conductive films made of conductive materials and stacked.

The cell line capping film 144 may be disposed on the cell conductive line 140. The cell line capping film 144 may extend in the second direction DR2 and along an upper surface of the cell conductive line 140. The cell line capping film 144 may include, for example, at least one of silicon nitride film, silicon oxynitride, silicon carbonitride, or silicon oxycarbonitride.

In a semiconductor memory device according to some embodiments, the cell line capping film 144 may include a silicon nitride film. The cell line capping film 144 is illustrated as being embodied as a single film. However, embodiments of the present disclosure are not limited thereto.

The bit line spacer 150 may be disposed on a sidewall of each of the cell conductive line 140 and the cell line capping film 144. The bit line spacer 150 extends in the second direction DR2.

The bit line spacer 150 is illustrated as being embodied as a single film. However, this is only for the convenience of illustration and the present disclosure is not limited thereto. That is, unlike what is illustrated, the bit line spacer 150 may have a multi-film structure. The bit line spacer 150 may include, but is not limited to, silicon oxide, silicon nitride, silicon oxynitride (SiON), silicon oxycarbonitride (SiOCN), air, or a combination thereof.

The cell insulating film 130 may be disposed on the substrate 100 and the cell element isolation film 105. More specifically, the cell insulating film 130 may be disposed on the upper surface of each of the substrate 100 and the cell element isolation film 105 in an area in which the bit line contact 146 and the storage contact 120 are not formed. The cell insulating film 130 may be formed between the substrate 100 and the cell conductive line 140, and between the cell element isolation film 105 and the cell conductive line 140.

The cell insulating film 130 may be a single film. However, as illustrated, the cell insulating film 130 may be a multi-film including a first cell insulating film 131 and a second cell insulating film 132. For example, the first cell insulating film 131 may include a silicon oxide film, and the second cell insulating film 132 may include a silicon nitride film. However, embodiments of the present disclosure are not limited thereto. Unlike the illustrated example, the cell insulating film 130 may be a triple film including a silicon oxide film, a silicon nitride film, and a silicon oxide film. However, embodiments of the present disclosure are not limited thereto.

The bit line contact 146 may be disposed between the cell conductive line 140 and the substrate 100. The cell conductive line 140 may be disposed on the bit line contact 146.

The bit line contact 146 may be disposed between the bit line connection portion 103a of the cell active area ACT and the cell conductive line 140. The bit line contact 146 may electrically connect the cell conductive line 140 and the substrate 100 to each other. The bit line contact 146 may be connected to the bit line connection portion 103a.

The bit line contact 146 may include an upper surface 146US connected to the cell conductive line 140. Although a width in the first direction DR1 of the bit line contact 146 is shown to be constant as the bit line contact 146 extends away from the upper surface 146US of the bit line contact, this is only for the convenience of illustration and the present disclosure is not limited thereto.

The bit line contact 146 may correspond to the direct contact DC. The bit line contact 146 may include, for example, at least one of a semiconductor material doped with an impurity, a conductive metal silicide, a conductive metal nitride, a conductive metal oxide, a metal, or a metal alloy.

In an area in which the cell conductive line 140 overlaps the bit line contact 146 in the fourth direction DR4, the bit line spacer 150 may be disposed on the substrate 100 and the cell element isolation film 105. The bit line spacer 150 may be disposed on a sidewall of each of the cell conductive line 140, the cell line capping film 144, and the bit line contact 146.

In an area in which the cell conductive line 140 non-overlaps (i.e., does not overlap) the bit line contact 146 in the fourth direction DR4, that is, the bit line contact 146 is not formed, the bit line spacer 150 may be disposed on the cell insulating film 130. The bit line spacer 150 may be disposed on a sidewall of each of the cell conductive line 140 and the cell line capping film 144.

The storage contact 120 may be disposed between the cell conductive lines 140 adjacent to each other in the first direction DR1. The storage contact 120 may be disposed on each of both opposing sides of the cell conductive line 140. More specifically, the storage contact 120 may be disposed between the bit line structures 140ST. The storage contact 120 may be disposed between the word lines WL adjacent to each other in the second direction DR2.

The storage contact 120 may overlap a portion of each of the substrate 100 and the cell element isolation film 105 between adjacent cell conductive lines 140. The storage contact 120 may be connected to the cell active area ACT. More specifically, the storage contact 120 may be connected to the storage connection portion 103b. In this regard, the storage contact 120 may correspond to the buried contact BC of FIG. 5.

The storage contact 120 may include, for example, at least one of an impurity-doped semiconductor material, a conductive silicide compound, a conductive metal nitride, a conductive metal carbide, a conductive metal carbonitride, a conductive metal oxide, or a metal.

The storage pad 160 may be disposed on the storage contact 120. The storage pad 160 may be electrically connected to the storage contact 120. The storage pad 160 may be connected to the storage connection portion 103b of the cell active area ACT. In this regard, the storage pad 160 may correspond to the landing pad LP of FIG. 5.

The storage pad 160 may overlap a portion of an upper surface of the bit line structure 140ST. The storage pad 160 may include at least one of, for example, a conductive silicide compound, a conductive metal nitride, a conductive metal carbide, a conductive metal oxide, or a metal.

A pad isolation insulating film 180 may be disposed on the storage pad 160 and the bit line structure 140ST. For example, the pad isolation insulating film 180 may be disposed on the cell line capping film 144.

The pad isolation insulating film 180 may define the storage pad 160 that constitutes each of a plurality of isolated areas. The pad isolation insulating film 180 may not be on (e.g., may not cover) an upper surface 160US of the storage pad 160. For example, based on an upper surface of the substrate 100, a vertical level of the upper surface 160US of the storage pad 160 may be equal to a vertical level of an upper surface 180US of the pad isolation insulating film 180. In other words, the upper surface 160US of the storage pad 160 may be coplanar with the upper surface 180US of the pad isolation insulating film 180.

The pad isolation insulating film 180 may include an insulating material and may electrically insulate a plurality of storage pads 160 from each other. For example, the pad isolation insulating film 180 may include at least one of a silicon oxide film, a silicon nitride film, a silicon nitride film, a silicon oxynitride film, or a silicon oxynitride film. However, embodiments of the present disclosure are not limited thereto.

An etch stop layer 220 may be disposed on the upper surface 160US of the storage pad 160 and the upper surface 180US of the pad isolation insulating film 180. The etch stop layer 220 may include, for example, at least one of silicon nitride (SiN), silicon carbonitride (SiCN), silicon oxycarbonitride (SiOCN), silicon oxycarbide (SiOC), or silicon boron nitride (SiBN).

The capacitor structure CS may be disposed on the storage pad 160. The capacitor structure CS is electrically connected to the storage pad 160. A portion of the capacitor structure CS may be disposed within the etch stop layer 220.

The capacitor structure CS may include, for example, a capacitor. The capacitor structure CS may include the lower electrode 301, the lower interfacial film 501, the dielectric film structure 400, the upper interfacial film 502, and the upper electrode 302.

The lower supporter pattern 141 may support the lower electrode 301. The upper supporter pattern 142 may support the upper electrode 302. The upper supporter pattern 142 may be disposed on the lower electrode 301.

The descriptions of the lower electrode 301, the dielectric film structure 400, and the upper electrode 302 may be substantially the same as those described above with reference to FIGS. 1 to 4, and thus are omitted below to avoid repeated description.

The descriptions of the lower supporter pattern 141 and the upper supporter pattern 142 may be substantially the same as those described above with reference to FIGS. 1 to 4, and thus are omitted below to avoid repeated description.

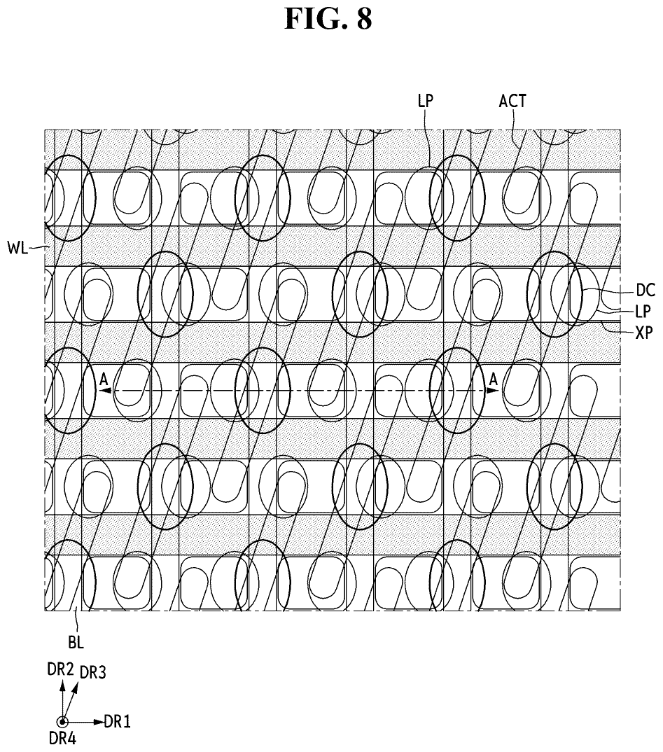

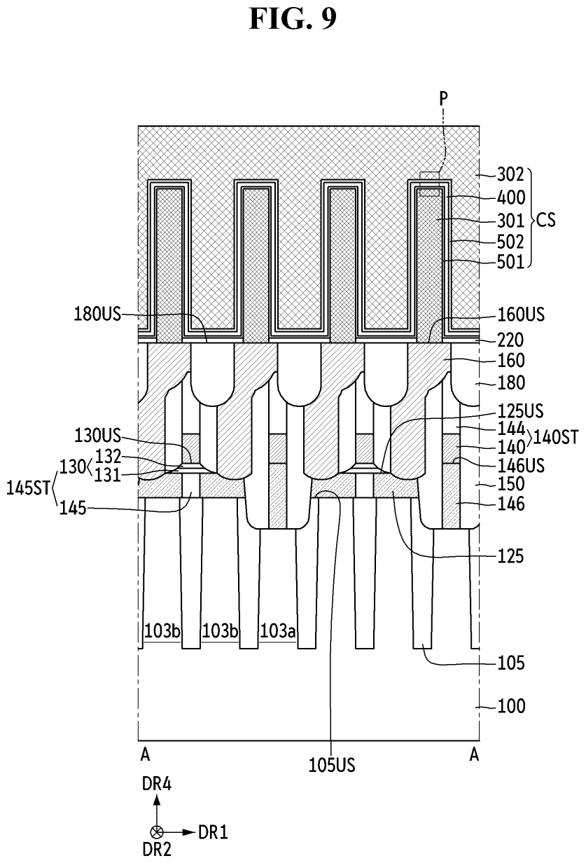

FIG. 8 is a layout diagram of a semiconductor memory device according to some further embodiments. FIG. 9 is a cross-sectional view taken along line A-A of FIG. 8. For convenience of description, the following description mainly focuses on differences thereof from the description above with reference to FIGS. 5 to 7. For reference, a P area illustrated in FIG. 9 (i.e., a portion P of FIG. 9) may correspond to FIG. 2, and the capacitor structure CS illustrated in FIG. 9 may correspond to the capacitor structure CS of FIG. 1.

Referring to FIGS. 8 and 9, a semiconductor memory device according to some embodiments includes a node pad XP that connects the cell active area ACT to the lower electrode 301, and does not include the buried contact BC of FIG. 5.

In this regard, the direct contact DC may mean a contact that electrically connects the cell active area ACT to the bit line BL. The node pad XP may be a contact pad that connects the cell active area ACT to the lower electrode 301 of the capacitor structure CS. Due to the arrangement structure, a contact area between the node pad XP and the cell active area ACT may be small. Accordingly, the conductive landing pad LP may be introduced to expand the contact area of the node pad XP with the cell active area ACT and thus the contact area of the node pad XP with the lower electrode 301 of the capacitor structure CS.

The landing pad LP may be disposed between the node pad XP and the lower electrode 301 of the capacitor structure CS. The contact area may be increased through the introduction of the landing pad LP, such that the contact resistance between the cell active area ACT and the lower electrode 301 of the capacitor structure CS may be reduced.

The node pad XP is disposed at a position overlapping each of both opposing ends of the cell active area ACT (e.g., in the fourth direction DR4). Thus, the landing pad LP may be disposed adjacent to each of both opposing ends of the cell active area ACT and may at least partially overlap with the node pad XP (e.g., in the fourth direction DR4). In other words, the node pad XP may be formed to overlap a portion of each of the cell active area ACT and the cell element isolation film 105 disposed between adjacent word lines WL and between adjacent bit lines BL.

The word line WL may extend across a portion of the cell active area ACT between the direct contacts DC or the node pads XP. As illustrated in FIG. 8, two word lines WL may extend across one cell active area ACT. Since the cell active area ACT extends along the third direction DR3, the word line WL may have an angle smaller than 90 degrees with respect to the cell active area ACT.

The direct contacts DC and the node pads XP may be arranged in a symmetrical manner. As a result, the direct contacts DC may be arranged in a straight line along the first direction DR1 and the second direction DR2. The node pads XP may be arranged in a straight line along the first direction DR1 and the second direction DR2. In one example, unlike the direct contact DC and the node pad XP, the landing pads LP may be arranged in a zigzag manner in the second direction DR2 along which the bit line BL extends. Further, the landing pads LP may overlap with the same portion of a side face of each bit-line BL in the first direction DR1 in which the word-line WL extends.

A node contact pad 125 may be disposed on the substrate 100. The node contact pad 125 may be disposed on the storage connection area 103b of the cell active area ACT. The node contact pad 125 is connected to the storage connection area 103b.

The node contact pad 125 may be disposed between cell conductive lines 140 adjacent to each other in the first direction DR1. Although not shown, the node contact pad 125 may be disposed between cell gate electrodes adjacent to each other in the second direction DR2. For example, the cell gate electrodes may correspond to the word lines WL.

Based on the upper surface 105US of the cell element isolation film 105, a vertical level of an upper surface 125US of the node contact pad 125 is lower than a vertical level of an upper surface 146US of the bit line contact 146. For example, the upper surface 125US of the node contact pad 125 may be closer to the substrate 100 than the upper surface 146US of the bit line contact 146 is in the fourth direction DR4. Based on the upper surface 105US of the cell element isolation film 105, the vertical level of the upper surface 125US of the node contact pad 125 is lower than a vertical level of a lower surface of the cell conductive line 140. For example, the upper surface 125US of the node contact pad 125 may be closer to the substrate 100 than the lower surface of the cell conductive line 140 is in the fourth direction DR4.

The node contact pad 125 may electrically connect the capacitor structure CS and the substrate 100 to each other. In this regard, the node contact pad 125 may correspond to the node pad XP.

The node contact pad 125 may include, for example, at least one of a semiconductor material doped with an impurity, a conductive metal silicide, a conductive metal nitride, a conductive metal oxide, a metal, or a metal alloy.

A pad isolation structure 145ST may isolate the node contact pads 125 adjacent to each other in the first direction DR1 from each other. Although not shown, the pad isolation structure 145ST may isolate the node contact pads 125 adjacent to each other in the second direction DR2 from each other. The pad isolation structure 145ST may be on the upper surface 125US of the node contact pad.

The pad isolation structure 145ST may include a pad isolation pattern 145 and an upper cell insulating film 130. The upper cell insulating film 130 may be disposed on the pad isolation pattern 145.

When the node contact pad 125 includes a first node contact pad and a second node contact pad spaced apart from each other in the first direction DR1, the pad isolation pattern 145 may isolate the first node contact pad and the second node contact pad from each other in the first direction DR1. Although not shown, the pad isolation pattern 145 may also isolate the node contact pads 125 adjacent to each other in the second direction DR2 from each other.

The upper cell insulating film 130 may be on the upper surface 125US of the node contact pad 125. When the node contact pad 125 includes the first node contact pad and the second node contact pad spaced apart from each other in the first direction DR1, the upper cell insulating film 130 may be on an upper surface of the first node contact pad and an upper surface of the second node contact pad.

The pad isolation pattern 145 and the upper cell insulating film 130 may be disposed between the bit line contacts 146 adjacent to each other in the second direction DR2 and/or the first direction DR1. The cell conductive line 140 may be disposed on an upper surface of the pad isolation structure 145ST. The cell conductive line 140 may be disposed on an upper surface 130US of the upper cell insulating film 130. The upper surface of the pad isolation structure 145ST may be an upper surface 130US of the upper cell insulating film 130. The upper surface of the pad isolation structure 145ST may be coplanar with the lower surface of the cell conductive line 140.

The pad isolation pattern 145 may include, for example, at least one of silicon nitride (SiN), silicon oxynitride (SiON), silicon oxide (SiO₂), silicon carbon nitride (SiCN), silicon oxycarbon nitride (SiOCN), or a combination thereof. The upper cell insulating film 130 may be embodied as a single film. However, as illustrated, the upper cell insulating film 130 may be a multi-film including a first upper cell insulating film 131 and a second upper cell insulating film 132. For example, the first upper cell insulating film 131 may include a silicon oxide film, and the second upper cell insulating film 132 may include a silicon nitride film. However, embodiments of the present disclosure are not limited thereto. A width in the first direction DR1 of the upper cell insulating film 130 is illustrated as decreasing as the upper cell insulating film 130 extends away from the substrate 100. However, embodiments of the present disclosure are not limited thereto.

The storage pad 160 may be disposed on each node contact pad 125. The storage pad 160 may be electrically connected to the node contact pad 125. The storage pad 160 may be connected to the storage connection area 103b of the cell active area ACT. In this regard, the storage pad 160 may correspond to the landing pad LP.

In the semiconductor memory device according to some embodiments, the storage pad 160 may extend to the node contact pad 125 so as to be connected to the node contact pad 125. The storage pad 160 may overlap a portion of an upper surface of the bit line structure 140ST (e.g., in the fourth direction DR4).

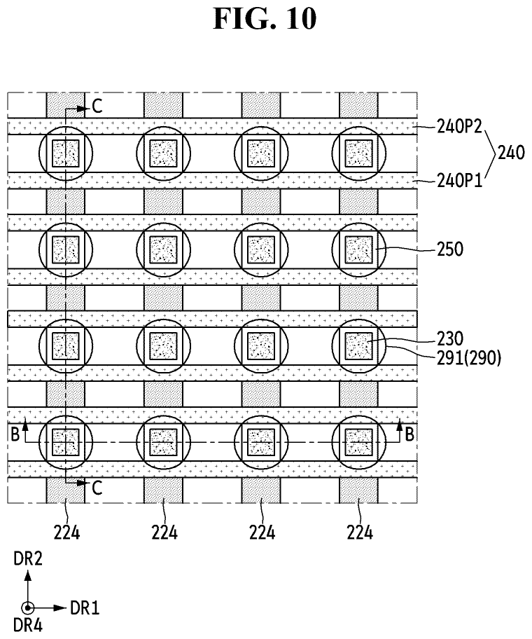

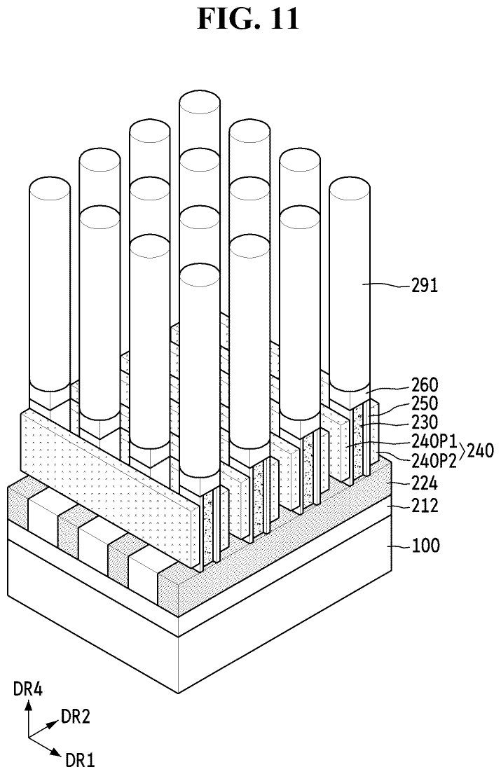

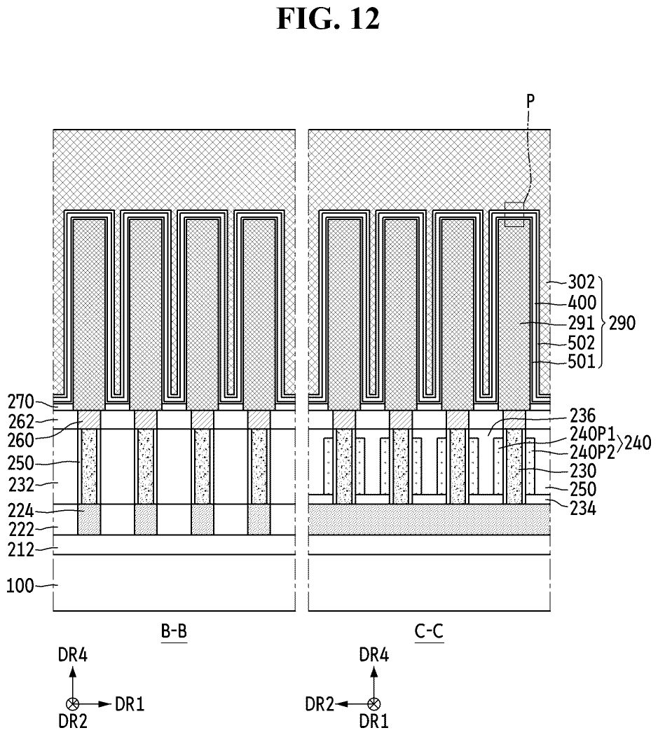

FIG. 10 is a layout diagram for illustrating a semiconductor memory device according to some embodiments. FIG. 11 is a perspective view for illustrating a semiconductor memory device according to some embodiments. FIG. 12 is a cross-sectional view taken along lines B-B and C-C of FIG. 10. For reference, the P area illustrated in FIG. 12 (i.e., a portion P of FIG. 12) may correspond to FIG. 2.

Referring to FIGS. 10 to 12, a semiconductor memory device according to some embodiments may include the substrate 100, a plurality of first conductive lines 224, a channel layer 230, a gate electrode 240, a gate insulating film 250, and a capacitor structure 290. A semiconductor memory device according to some embodiments may be a memory device including a vertical channel transistor (VCT). The vertical channel transistor may refer to a structure in which a channel length of the channel layer 230 extends in a vertical direction from the substrate 100 (e.g., in the fourth direction DR4).

A first lower insulating film 212 may be disposed on the substrate 100. The plurality of first conductive lines 224 may be disposed on the first lower insulating film 212 and may be spaced apart from each other in a first direction DR1 and may extend in the second direction DR2. A plurality of first insulating patterns 222 may be disposed on the first lower insulating film 212 so as to fill a space between adjacent one of the plurality of first conductive lines 224. The plurality of first insulating patterns 222 may extend in the second direction DR2. An upper surface of each of the plurality of first insulating patterns 222 may be disposed at the same level as that of (i.e., may be coplanar with) an upper surface of the plurality of first conductive lines 224. The plurality of first conductive lines 224 may function as a bit line.

Each of the plurality of first conductive lines 224 may include a doped semiconductor material, a metal, a metal alloy, a conductive metal nitride, a conductive metal silicide, a conductive metal oxide, or a combination thereof. For example, each of the plurality of first conductive lines 224 may be made of, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or a combination thereof. Each of the plurality of first conductive lines 224 may include a single layer or multiple layers made of the aforementioned materials. In some embodiments, each of the plurality of first conductive lines 224 may include graphene, carbon nanotubes, or a combination thereof.

The channel layers 230 may be disposed on the plurality of first conductive lines 224 and may be arranged in a matrix form and may be spaced apart from each other in the first direction DR1 and the second direction DR2. Each of the channel layers 230 may have a first width along the first direction DR1 and a first height along the fourth direction DR4, and the first height may be greater than the first width. In this regard, the fourth direction DR4 may be, for example, a direction perpendicular to an upper surface of the substrate 100. For example, the first height may be in a range of about 2 to 10 times of the first width. However, embodiments of the present disclosure are not limited thereto. A bottom portion of the channel layer 230 functions as a first source/drain area (not shown), an upper portion of the channel layer 230 functions as a second source/drain area (not shown), and a portion of the channel layer 230 between the first and second source/drain areas may function as a channel area (not shown).

In some embodiments, the channel layer 230 may include an oxide semiconductor. For example, the oxide semiconductor may include InGaZnO, InGaSiO, InSnZnO, InZnO, ZnO, ZnSnO, ZnON, ZrZnSnO, SnO, HfInZnO, GaZnSnO, AlZnSnO, YbGaZnO, InGaO, or a combination thereof. The channel layer 230 may include a single layer or multiple layers made of the oxide semiconductor. In some embodiments, the channel layer 230 may have a band gap energy greater than a band gap energy of silicon. For example, the channel layer 230 may have a band gap energy of about 1.5 eV to 5.6 eV. For example, the channel layer 230 may have optimal channel performance when it has a band gap energy of about 2.0 eV to 4.0 eV. For example, the channel layer 230 may be polycrystalline or amorphous. However, embodiments of the present disclosure are not limited thereto. In some embodiments, the channel layer 230 may include graphene, carbon nanotubes, or a combination thereof.

The gate electrode 240 may be disposed on each of both opposing sidewalls of the channel layer 230 and may extend in the first direction DR1. The gate electrode 240 may include a first sub-gate electrode 240P1 facing a first sidewall of the channel layer 230 and a second sub-gate electrode 240P2 facing a second sidewall opposite to the first sidewall of the channel layer 230. Since one channel layer 230 is disposed between the first sub-gate electrode 240P1 and the second sub-gate electrode 240P2, the semiconductor device may have a dual-gate transistor structure. However, the present disclosure is not limited thereto, and the second sub-gate electrode 240P2 may be omitted and only the first sub-gate electrode 240P1 facing the first sidewall of the channel layer 230 may be formed, thereby implementing a single-gate transistor structure. The gate electrode 240 may include, for example, at least one of a semiconductor material doped with an impurity, a conductive silicide compound, a conductive metal nitride, a two-dimensional 2D material, or a metal.

A gate insulating film 250 surrounds a sidewall of the channel layer 230 and may be interposed between the channel layer 230 and the gate electrode 240. For example, as illustrated in FIG. 10, an entire sidewall of the channel layer 230 may be surrounded with the gate insulating film 250, and a portion of the sidewall of the gate electrode 240 may be in contact with the gate insulating film 250. In some further embodiments, the gate insulating film 250 may extend in the extension direction of the gate electrode 240 (i.e., the first direction DR1), and only two sidewalls of the channel layer 230 facing the gate electrode 240 may be in contact with the gate insulating film 250. In some embodiments, the gate insulating film 250 may be made of a silicon oxide film, a silicon nitride film, a high-k material film having a higher dielectric constant than that of the silicon oxide film, or a combination thereof.

A plurality of second insulating patterns 232 may extend along the second direction DR2 and may be disposed on the plurality of first insulating patterns 222. The channel layer 230 may be disposed between two adjacent second insulating patterns 232 among the plurality of second insulating patterns 232. Furthermore, a first buried layer 234 and a second buried layer 236 may be disposed in a space between two adjacent channel layers 230 and between two adjacent second insulating patterns 232. The first buried layer 234 may be disposed in a bottom of the space between the two adjacent channel layers 230. The second buried layer 236 may be formed to fill the remainder of the space between the two adjacent channel layers 230 as defined on the first buried layer 234. An upper surface of the second buried layer 236 may be disposed at the same level as that of an upper surface of the channel layer 230, and the second buried layer 236 may be on (e.g., may cover) an upper surface of the gate electrode 240. In some embodiments, the plurality of second insulating patterns 232 may be formed as a material layer continuous and monolithic with the plurality of first insulating patterns 222, and/or the second buried layer 236 may be formed as a material layer continuous and monolithic with the first buried layer 234.

A capacitor contact 260 may be disposed on the channel layer 230. The capacitor contacts 260 may vertically overlap with the channel layer 230 (e.g., in the fourth direction DR4) and may be arranged in a matrix form and may be spaced apart from each other in the first direction DR1 and the second direction DR2. The capacitor contact 260 may be made of, but is not limited to, doped polysilicon, Al, Cu, Ti, Ta, Ru, W, Mo, Pt, Ni, Co, TiN, TaN, WN, NON, TiAl, TiAIN, TiSi, TiSiN, TaSi, TaSIN, RuTiN, NiSi, CoSi, IrO, RuO, or a combination thereof. An upper insulating film 262 may be disposed on the plurality of the second insulating pattern 232 and the second buried layer 236 so as to surround a sidewall of the capacitor contact 260.

A second etch stop layer 270 may be disposed on the upper insulating film 262. The capacitor structure 290 may be disposed on the second etch stop layer 270. The capacitor structure 290 may include the lower electrode 291, the lower interfacial film 501, the dielectric film structure 400, the upper interfacial film 502, and the upper electrode 302. The lower electrode 291 may extend through the second etch stop layer 270 so as to be electrically connected to an upper surface of the capacitor contact 260. The lower electrode 291 may be formed in a pillar shape extending in the fourth direction DR4. However, embodiments of the present disclosure are not limited thereto. In some embodiments, the lower electrodes 291 may be disposed so as to vertically overlap with the capacitor contact 260 and may be arranged in a matrix form and be spaced apart from each other in the first direction DR1 and the second direction DR2. In some embodiments, the landing pad (not shown) may be further disposed between the capacitor contact 260 and the lower electrode 291, so that the lower electrodes 291 may be arranged in a hexagonal shape.

The dielectric film structure 400 may be formed on the lower electrode 291. In some embodiments, the dielectric film structure 400 may extend along a profile of a side surface and an upper surface of the lower electrode 291.

The upper electrode 302 may be formed on the dielectric film structure 400. In FIG. 12, the upper electrode 302 is illustrated as filling only an area between adjacent lower electrodes 291. However, this is only an example. In another example, the upper electrode 302 may extend along a profile of the dielectric film structure 400.

The capacitor structure 290, the lower electrode 291, the dielectric film structure 400, and the upper electrode 302 may correspond to the capacitor structure CS, the lower electrode 301, the dielectric film structure 400, and the upper electrode 302 as described above with reference to FIGS. 1 to 7, respectively.

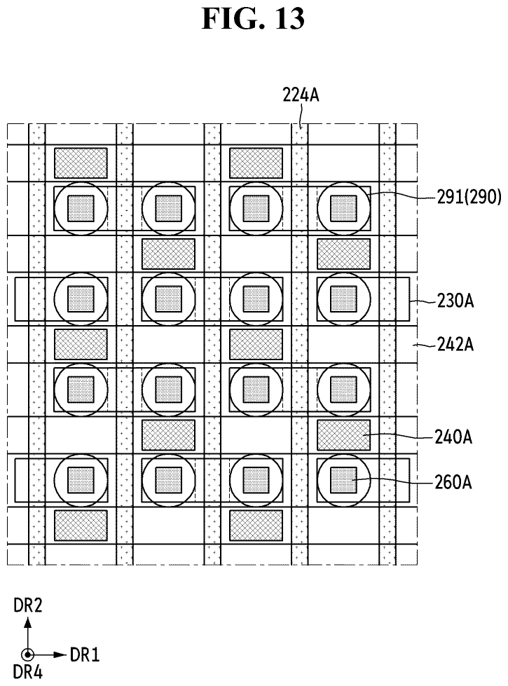

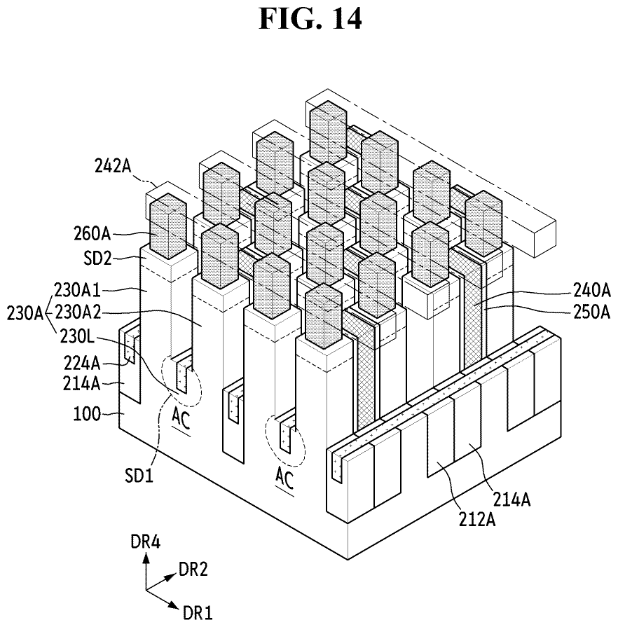

FIG. 13 is a layout diagram for illustrating a semiconductor memory device according to some embodiments. FIG. 14 is a perspective view for illustrating a semiconductor memory device according to some embodiments. For reference, the capacitor structure 290 illustrated in FIG. 13 may correspond to the capacitor structure CS of FIG. 1.

Referring to FIG. 13 and FIG. 14, a semiconductor memory device according to some embodiments may include the substrate 100, a plurality of first conductive lines 224A, a channel structure 230A, a contact gate electrode 240A, a plurality of second conductive lines 242A, and the capacitor structure 290. The semiconductor memory device according to some embodiments may be a memory device including a vertical channel transistor (VCT).

A plurality of active areas AC may be defined in the substrate 100 by a first element isolation pattern 212A and a second element isolation pattern 214A. The channel structure 230A may be disposed within each active area AC. The channel structure 230A may include a first active pillar 230A1 and a second active pillar 230A2 extending in a vertical direction (e.g., in the fourth direction DR4), and a connection portion 230L connected to a bottom of the first active pillar 230A1 and a bottom of the second active pillar 230A2. A third source/drain area SD1 may be disposed within the connection portion 230L. A fourth source/drain area SD2 may constitute a top portion of each of the first and second active pillars 230A1 and 230A2. Each of the first active pillar 230A1 and the second active pillar 230A2 may constitute an independent unit memory cell.

Each of the plurality of first conductive lines 224A may extend in a direction intersecting the extension direction of each of the plurality of active areas AC, for example, may extend in the second direction DR2. One of the plurality of first conductive lines 224A may be disposed on the connection portion 230L and between the first active pillar 230A1 and the second active pillar 230A2. One first conductive line 224A may be disposed on the third source/drain area SD1. Another first conductive line 224A adjacent to one first conductive line 224A may be disposed between two channel structures 230A. One of the plurality of first conductive lines 224A may function as a common bit line included in two unit memory cells respectively including the first active pillar 230A1 and the second active pillar 230A2 respectively disposed on both opposing sides of one first conductive lines 224A.

A contact gate electrode 240A may be disposed between two channel structures 230A adjacent to each other in the second direction DR2. For example, a contact gate electrode 240A may be disposed between the first active pillar 230A1 included in one channel structure 230A and the second active pillar 230A2 included in another channel structure 230A adjacent thereto. One contact gate electrode 240A may be shared by the first active pillar 230A1 and the second active pillar 230A2 respectively disposed on both opposing side walls thereof. A fourth gate insulating film 250A may be disposed between the contact gate electrode 240A and the first active pillar 230A1 and between the contact gate electrode 240A and the second active pillar 230A2. The plurality of second conductive lines 242A may extend in the first direction DR1 and may be disposed on an upper surface of the contact gate electrode 240A. The plurality of second conductive lines 242A may function as a word line of a semiconductor memory device.

The capacitor contact 260A may be disposed on the channel structure 230A. The capacitor contact 260A may be disposed on the fourth source/drain area SD2, and the capacitor structure 290 may be disposed on the capacitor contact 260A.

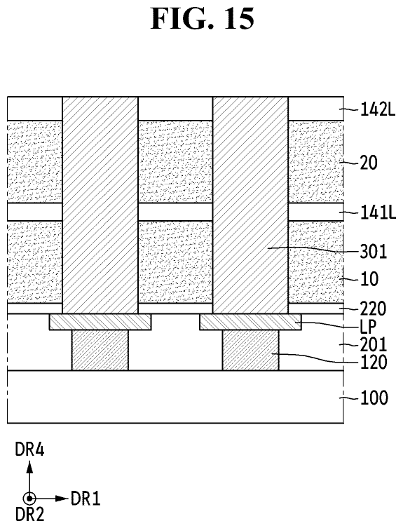

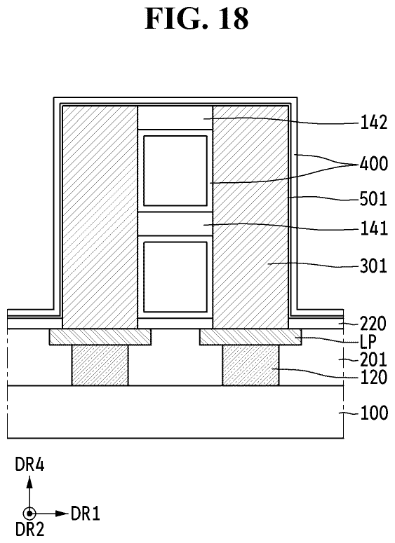

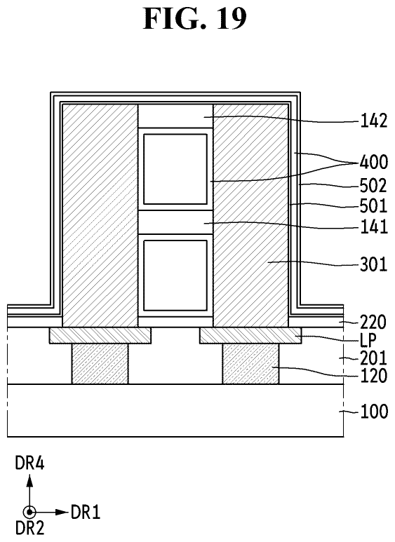

FIGS. 15 to 21 are diagrams of intermediate structures corresponding to intermediate steps of a method for manufacturing a semiconductor memory device according to some embodiments. For convenience of description, the following description mainly focuses on differences thereof from the description above with reference to FIGS. 5 to 7.

Referring to FIG. 15, the first interlayer insulating film 201 may be formed on the substrate 100. The storage contact 120 and the landing pad LP may be formed within the first interlayer insulating film 201. Subsequently, an etch stop layer 220, a first mold layer 10, a first supporter layer 141L, a second mold layer 20, and a second supporter layer 142L may be sequentially formed on the first interlayer insulating film 201.

Subsequently, a lower electrode pattern 301 that extends through the etch stop layer 220, the first mold layer 10, the first supporter layer 141L, the second mold layer 20, and the second supporter layer 142L in the fourth direction DR4 (e.g., in a vertical direction) may be formed on the landing pad LP.

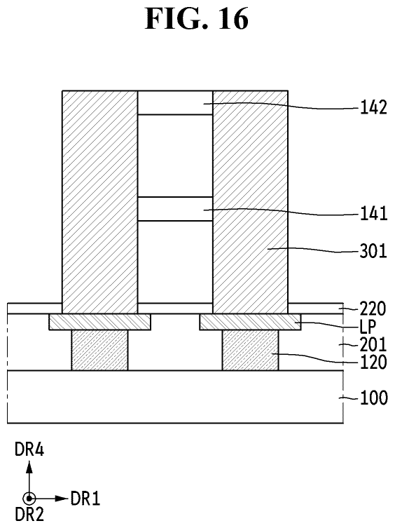

Referring to FIG. 16, a first supporter pattern 141 and a second supporter pattern 142 connecting adjacent lower electrodes 301 to each other may be formed. Each of the first supporter pattern 141 and the second supporter pattern 142 may be in contact with a portion of a side wall of the lower electrode 301.

A portion of the second supporter layer 142L may be removed to form the second supporter pattern 142. The second mold layer 20 may be removed through an area where the second supporter pattern 142 is not formed. Subsequently, a portion of the first supporter layer 141L may be removed to form the first supporter pattern 141. The first mold layer 10 may be removed through an area where the first supporter pattern 141 is not formed. The first mold layer 10 and the second mold layer 20 may be removed to expose a side wall of the lower electrode pattern 301, thereby forming the lower electrode 301. Therefore, a space may be formed between the etch stop layer 220 and the first supporter pattern 141 and between the first supporter pattern 141 and the second supporter pattern 142.

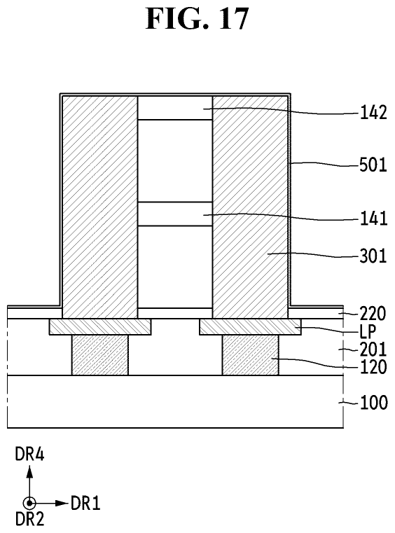

Referring to FIGS. 17 to 19, the lower interfacial film 501 may be formed between the exposed etch stop layer 220 and the exposed first supporter pattern 141 and between the exposed first supporter pattern 141 and the exposed second supporter pattern 142. The lower interfacial film 501 may be formed on an upper surface of the etch stop layer 220, a lower surface and an upper surface of the first supporter pattern 141, and a lower surface and an upper surface of the second supporter pattern 142.

Subsequently, the dielectric film structure 400 may be formed on the lower interfacial film 501. The dielectric film structure 400 may be formed along a profile of the lower interfacial film 501.

Subsequently, an upper interfacial film 502 may be formed on an upper surface of the dielectric film structure 400. The upper interfacial film 502 may be formed along a profile of the dielectric film structure 400.

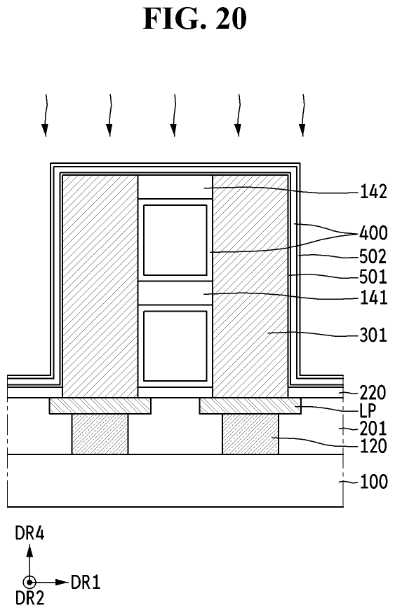

Referring to FIG. 20, the lower interfacial film 501, the dielectric film structure 400, and the upper interfacial film 502 may be formed, and then, an annealing process may be performed thereon. The annealing process may be performed at a temperature range of, for example, 200° C. to 700° C.

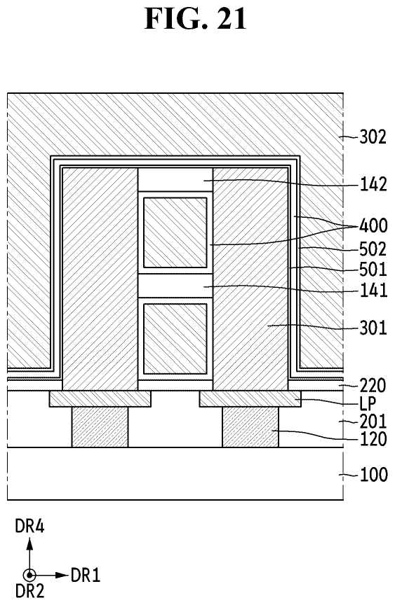

Referring to FIG. 21, after the annealing process has been performed, the upper electrode 302 may be formed. The upper electrode 302 may be formed on the upper interfacial film 502. The upper electrode 302 may be formed to be on (e.g., to cover) a side wall and an upper surface of the lower electrode 301. Furthermore, the upper electrode 302 may be formed between the etch stop layer 220 and the first supporter pattern 141, and between the first supporter pattern 141 and the second supporter pattern 142.

Although FIG. 20 and FIG. 21 illustrate that the upper electrode is formed after the annealing process has been performed, the present disclosure is not limited thereto. In another example, the lower interfacial film 501, the dielectric film structure 400, and the upper interfacial film 502 may be formed, and the upper electrode 302 may be formed, and then, the annealing process may be performed thereon.

Then, referring back to FIG. 1, the second interlayer insulating film 202 may be formed on the upper electrode 302, thereby manufacturing the semiconductor memory device as illustrated in FIG. 1.

Although example embodiments of the present disclosure have been described above with reference to the accompanying drawings, the present disclosure is not limited to the above-described embodiments and may be implemented in various different forms. A person skilled in the art will appreciate that the present disclosure may be embodied in other concrete forms without changing the scope or essential characteristics of the present disclosure. Therefore, it will be understood that the embodiments as described above are not restrictive but illustrative in all respects.

In concluding the detailed description, those skilled in the art will appreciate that many variations and modifications may be made to the above-described example embodiments without substantially departing from the scope of the present disclosure. Therefore, the example embodiments of the present disclosure are used in a generic and descriptive sense only and not for purposes of limitation.

What is claimed is:

1. A semiconductor memory device comprising:
a first electrode and a second electrode spaced apart from each other;
a dielectric film structure between the first electrode and the second electrode;
a first interfacial film between the first electrode and the dielectric film structure; and
a second interfacial film between the second electrode and the dielectric film structure,
wherein the dielectric film structure includes a first dielectric film and a second dielectric film sequentially stacked on the first interfacial film,
wherein the first dielectric film includes an oxide of at least one of titanium (Ti) or strontium (Sr) having a first dielectric constant greater than 20, and
wherein the second dielectric film includes a material having a second dielectric constant that is smaller than the first dielectric constant by at least 20.

2. The semiconductor memory device of claim 1, wherein the dielectric film structure includes a first dielectric film structure and a second dielectric film structure,
wherein each of the first dielectric film structure and the second dielectric film structure includes the first dielectric film and the second dielectric film, and
wherein the first dielectric film and the second dielectric film of the first dielectric film structure and the first dielectric film and the second dielectric film of the second dielectric film structure are sequentially stacked on top of each other.

3. The semiconductor memory device of claim 2, wherein the second dielectric film of at least one of the first dielectric film structure or the second dielectric film structure is in direct contact with the second interfacial film.

4. The semiconductor memory device of claim 1, wherein a thickness of the second dielectric film is in a range of 30% to 60% of a thickness of the first dielectric film.

5. The semiconductor memory device of claim 1, wherein a thickness of the second interfacial film is greater than a thickness of the first interfacial film.

6. The semiconductor memory device of claim 5, wherein the thickness of the first interfacial film is in a range of 1 to 10 angstroms, and the thickness of the second interfacial film is in a range of 5 to 20 angstroms.

7. The semiconductor memory device of claim 1, wherein the dielectric film structure includes a first dielectric film structure and a second dielectric film structure,
wherein the first dielectric film structure includes the first dielectric film and the second dielectric film,
wherein the second dielectric film structure includes a third dielectric film and a fourth dielectric film,
wherein the third dielectric film includes an oxide of at least one of titanium (Ti) or strontium (Sr) having a third dielectric constant greater than 20, and
wherein the fourth dielectric film includes a material having a fourth dielectric constant that is smaller than the third dielectric constant by at least 20.

8. The semiconductor memory device of claim 7, wherein the third dielectric film and the first dielectric film include a same material.

9. The semiconductor memory device of claim 7, wherein a combined thickness of the second dielectric film and the fourth dielectric film is in a range of 30% to 60% of a combined thickness of the first dielectric film and the third dielectric film.

10. The semiconductor memory device of claim 7, wherein the dielectric film structure includes a plurality of dielectric film structures, and
wherein the first to fourth dielectric films are repeatedly stacked in sequence across the plurality of dielectric film structures, with alternating ones of the plurality of dielectric film structures including either the first and second dielectric films or the third and fourth dielectric films.

11. The semiconductor memory device of claim 10, wherein the fourth dielectric film of at least one of the plurality of dielectric film structures is in direct contact with the second interfacial film.

12. The semiconductor memory device of claim 1, wherein at least one of the first electrode or the second electrode includes a metal other than ruthenium (Ru), platinum (Pt), gold (Au), and palladium (Pd).

13. The semiconductor memory device of claim 1, wherein the second dielectric film includes an oxide of at least one of aluminum (Al), yttrium (Y), lanthanum (La), boron (B), or indium (In).

14. The semiconductor memory device of claim 1, wherein the first interfacial film includes an oxide or a nitride of at least one of tantalum (Ta), antimony (Sb), molybdenum (Mo), cobalt (Co), niobium (Nb), copper (Cu), nickel (Ni), vanadium (V), or tungsten (W).

15. The semiconductor memory device of claim 1, wherein the first interfacial film is a single-layered film.

16. A semiconductor memory device comprising:
a first electrode and a second electrode spaced apart from each other; and
a first interfacial film, a plurality of dielectric film structures, and a second interfacial film that are between the first electrode and the second electrode and are sequentially stacked,
wherein the first interfacial film is in direct contact with the first electrode, and the second interfacial film is in direct contact with the second electrode,
wherein the plurality of dielectric film structures are sequentially stacked on the first interfacial film,
wherein a first one of the plurality of dielectric film structures includes first and second dielectric films, and a second one of the plurality of dielectric film structures includes third and fourth dielectric films,
wherein the first to fourth dielectric films respectively include first to fourth materials having respective first to fourth dielectric constants,
wherein each of the first dielectric constant and the third dielectric constant is greater than 20, and
wherein each of the second dielectric constant and the fourth dielectric constant is smaller than each of the first dielectric constant and the third dielectric constant by at least 20.

17. The semiconductor memory device of claim 16, wherein the first dielectric film and the third dielectric film include a same material, and
wherein the second dielectric film and the fourth dielectric film include different materials.

18. The semiconductor memory device of claim 16, wherein the first dielectric film and the third dielectric film include different materials, and
wherein the second dielectric film and the fourth dielectric film include a same material.

19. A semiconductor memory device comprising:
a substrate including an active area that is defined by an element isolation film and that extends in a first direction, wherein the active area includes a first portion and a second portion on opposing sides of the first portion;
a word line extending in a second direction different from the first direction, wherein the word line extends across an area between the first portion of the active area and the second portion of the active area;
a bit line contact electrically connected to the first portion of the active area;
a bit line on the bit line contact and electrically connected to the bit line contact, wherein the bit line extends in a third direction different from the first direction and the second direction; and
a capacitor structure including a lower electrode electrically connected to the second portion of the active area, the capacitor structure further including a lower interfacial film, a dielectric film structure, an upper interfacial film, and an upper electrode sequentially stacked on the lower electrode,
wherein the dielectric film structure includes a first dielectric film structure and a second dielectric film structure,
wherein each of the first dielectric film structure and the second dielectric film structure includes a first dielectric film and a second dielectric film,
wherein the first dielectric film and the second dielectric film of the first dielectric film structure and the first dielectric film and the second dielectric film of the second dielectric film structure are sequentially stacked on top of each other,
wherein the first dielectric film includes an oxide of at least one of titanium (Ti) or strontium (Sr) having a first dielectric constant greater than 20, and
wherein the second dielectric film includes a material having a second dielectric constant that is smaller than the first dielectric constant by at least 20.

20. The semiconductor memory device of claim 19, wherein the dielectric film structure further includes a third dielectric film structure,
wherein the third dielectric film structure includes a third dielectric film and a fourth dielectric film,
wherein the third dielectric film includes an oxide of at least one of titanium (Ti) or strontium (Sr) having a third dielectric constant greater than 20, and
wherein the fourth dielectric film includes a material having a fourth dielectric constant that is smaller than the third dielectric constant by at least 20.
